(19) United States
(12) Patent Application Publication
(10) Pub. No.: US 2022/0311591 A1
(43) Pub. Date: Sep. 29, 2022

(54) KRAMERS-KRONIG RECEPTION-BASED THz SIGNAL RECEPTION APPARATUS AND FREQUENCY OFFSET COMPENSATION METHOD USING THE SAME

(71) Applicant: ELECTRONICS AND TELECOMMUNICATIONS RESEARCH INSTITUTE, Daejeon (KR)

(72) Inventors: Minkyu SUNG, Seoul (KR); Eon-sang KIM, Daejeon (KR); Sang Rok MOON, Daejeon (KR); Seung-Hyun CHO, Sejong-si (KR)

(21) Appl. No.: 17/698,600

(22) Filed: Mar. 18, 2022

(30) Foreign Application Priority Data
Mar. 24, 2021 (KR) 10-2021-0037784

(51) Int. Cl. H04L 7/00

(52) U.S. Cl. CPC H04L 7/0016; H04L 7/0075

(57) ABSTRACT

Provided are a Kramers—Kronig (KK) reception-based terahertz (THz) signal reception apparatus and a method for compensating a frequency offset using the same. A method of compensating for a frequency offset performed by a THz signal reception apparatus includes receiving, from a THz signal transmission apparatus, a THz signal including carrier signals corresponding to three different frequency bands, extracting, from the received THz signal, a reference carrier included in the THz signal or a sampling clock generated in a process of generating a data signal, and compensating for a frequency offset generated in a process of transmitting the THz signal by using the extracted reference carrier or sampling clock.

### CROSS-REFERENCE TO RELATED APPLICATION

This application claims the benefit of Korean Patent Application No. 10-2021-0037784 filed on Mar. 24, 2021, in the Korean Intellectual Property Office, the entire disclosure of which is incorporated herein by reference for all purposes.

### BACKGROUND

### 1. Field of the Invention

One or more example embodiments relate to a Kramers-Kronig reception (KK reception)-based terahertz (THz) signal reception apparatus and a frequency offset compensation method using the same, and more particularly, to an apparatus and method of compensating for a frequency offset generated in a process of transmitting a THz signal by using a reference carrier for KK reception included in the THz signal or a sampling clock generated in a process of generating a data signal.

### 2. Description of Related Art

In order to implement a short-range wireless transmission system using a THz frequency band, a photonics-based THz short-range transmission system using a heterodyne photo-mixing method by using two optical carriers is being studied. In particular, in 2020, according to Nature Photonics, a world-renowned academic journal, based on a Kramers—Kronig receiver (KK receiver), 110-m transmission at 30 Gbaud-rate in 0.3 THz band was successful, and thus frequency efficiency was increased by overcoming a signal-to-signal beat interference (SSBI) caused by a Schottky-barrier-diode (SBD)-based detection method.

However, in the above-described system, a phase and frequency between a reference carrier for the KK receiver, a phase and frequency between a data signal carrier for a data signal to be transmitted and an optical carrier for generating a THz band signal are not locked, resulting in an issue related to a frequency offset.

In the SBD-based detection method according to a related art, only an envelope of a signal is detected, and thus there is immunity to a phase and frequency offset caused by a free-running optical source. However, the KK receiver recovers an optical field, and thus an issue related to the phase and frequency offset occurs again. This issue causes degradation of a signal, and thus compensation is required.

### SUMMARY

Example embodiments provide an apparatus and method of compensating for a frequency offset generated in a process of transmitting a THz signal by using a reference carrier for KK reception included in the THz signal or a sampling clock generated in a process of generating a data signal.

According to an aspect, there is provided a method of compensating for a frequency offset performed by a THz signal reception apparatus, the method including receiving, from a THz signal transmission apparatus, a THz signal including carrier signals corresponding to three different frequency bands, extracting, from the received THz signal, a reference carrier included in the THz signal or a sampling clock generated in a process of generating a data signal, and compensating for a frequency offset generated in a process of transmitting the THz signal by using the extracted reference carrier or sampling clock.

The THz signal may be generated by photo-mixing the reference carrier, a data signal carrier for a data signal to be transmitted, and an optical carrier for generating a THz band signal.

The compensating may include identifying initial frequency spectrum information on the reference carrier or sampling clock of the THz signal received from the THz signal transmission apparatus, extracting current frequency spectrum information on the reference carrier or sampling clock of the received THz signal, and compensating for the frequency offset of the THz signal determined through the initial frequency spectrum information and the current frequency spectrum information on the reference carrier or sampling clock.

The receiving may include detecting the THz signal by using an SBD-based detection method.

According to another aspect, there is provided a THz signal reception apparatus including a receiver configured to receive, from a THz signal transmission apparatus, a THz signal including carrier signals corresponding to three different frequency bands, and a processor configured to extract, from the THz signal received through the receiver, a reference carrier included in the THz signal or a sampling clock generated in a process of generating a data signal, and compensate for a frequency offset generated in a process of transmitting the THz signal by using the extracted reference carrier or sampling clock.

The THz signal may be generated by photo-mixing the reference carrier, a data signal carrier for a data signal to be transmitted, and an optical carrier for a THz band signal.

The processor may be configured to identify initial frequency spectrum information on the reference carrier or sampling clock of the THz signal received from the THz signal transmission apparatus, extract current frequency spectrum information on the reference carrier or sampling clock of the received THz signal, and compensate for the frequency offset of the THz signal determined through the initial frequency spectrum information and the current frequency spectrum information on the reference carrier or sampling clock.

An SBD-based detection method may be applied to the receiver.

According to still another aspect, there is provided a method of compensating for a frequency offset performed by a THz signal reception apparatus, the method including receiving, from a THz signal transmission apparatus, a THz signal including carrier signals corresponding to three different frequency bands, and converting the THz signal to a digital form, extracting, from the THz signal converted to the digital form, a reference carrier included in the THz signal or a sampling clock generated in a process of generating a data signal, compensating for a frequency offset generated in a process of transmitting the THz signal by using the extracted reference carrier or sampling clock, performing KK reception-based digital signal processing on the THz signal for which the frequency offset is compensated, and performing coherent-based digital signal processing on the THz signal on which the KK reception-based digital signal processing is performed.

The THz signal may be generated by photo-mixing the reference carrier, a data signal carrier for a data signal to be transmitted, and an optical carrier for generating a THz band signal.

The compensating may include identifying initial frequency spectrum information on the reference carrier or sampling clock of the THz signal received from the THz signal transmission apparatus, extracting current frequency spectrum information on the reference carrier or sampling clock of the received THz signal, and compensating for the frequency offset of the THz signal determined through the initial frequency spectrum information and the current frequency spectrum information on the reference carrier or sampling clock.

The THz signal may be detected by using an SBD-based detection method.

According to still another aspect, there is provided a THz signal reception apparatus including an analog-to-digital converter (ADC) configured to receive, from a THz signal transmission apparatus, a THz signal including carrier signals corresponding to three different frequency bands, and convert the THz signal to a digital form, a first processor configured to extract, from the TH signal converted to the digital form, a reference carrier included in the THz signal or a sampling clock generated in a process of generating a data signal, and compensate for a frequency offset generated in a process of transmitting the THz signal by using the extracted reference carrier or sampling clock, a second processor configured to perform KK reception-based digital signal processing on the THz signal for which the frequency offset is compensated, and a third processor configured to perform coherent-based digital signal processing on the THz signal on which the KK reception-based digital signal processing is performed.

The THz signal may be generated by photo-mixing a reference carrier for the KK reception, a data signal carrier for a data signal to be transmitted, and an optical carrier for generating a THz band signal.

The first processor may be configured to identify initial frequency spectrum information on the reference carrier or sampling clock of the THz signal received from the THz signal transmission apparatus, extract current frequency spectrum information on the reference carrier or sampling clock of the received THz signal, and compensate for the frequency offset of the THz signal determined through the initial frequency spectrum information and the current frequency spectrum information on the reference carrier or sampling clock.

The THz signal may be detected by using an SBD-based detection method.

Additional aspects of example embodiments will be set forth in part in the description which follows and, in part, will be apparent from the description, or may be learned by practice of the disclosure.

According to example embodiments, it is possible to compensate for a frequency offset generated in a process of transmitting a THz signal without addition of a pilot signal and the like by using a reference carrier for KK reception included in the THz signal or a sampling clock generated in a process of generating a data signal.

### BRIEF DESCRIPTION OF THE DRAWINGS

These and/or other aspects, features, and advantages of the invention will become apparent and more readily appreciated from the following description of example embodiments, taken in conjunction with the accompanying drawings of which:

FIG. 1 is a diagram illustrating a KK reception-based THz signal transmission system according to an example embodiment;

FIG. 2 is a diagram illustrating a frequency spectrum before photo-mixing of a KK reception-based THz signal according to an example embodiment; and

FIG. 3 is a diagram illustrating a method of compensating for a frequency offset according to an example embodiment.

### DETAILED DESCRIPTION OF THE INVENTION

Hereinafter, example embodiments will be described in detail with reference to the accompanying drawings.

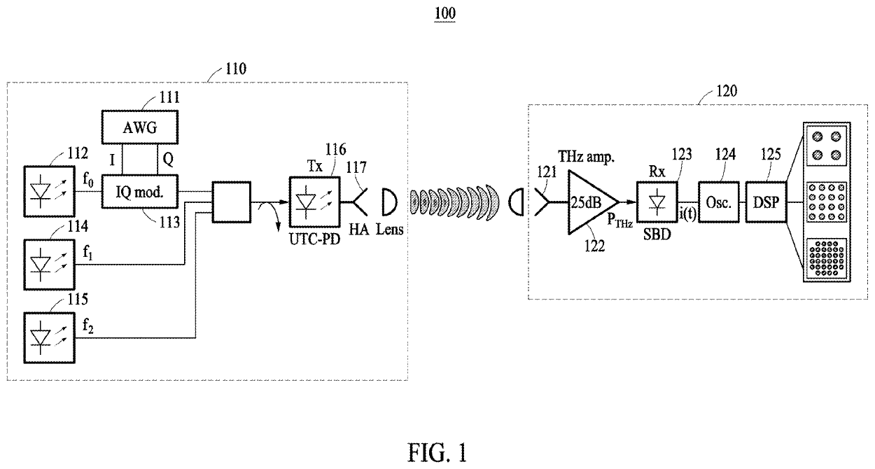

FIG. 1 is a diagram illustrating a KK reception-based THz signal transmitting system according to an example embodiment.

Referring to FIG. 1, a KK reception-based THz signal transmission system 100 may include a THz signal transmission apparatus 110 and a THz signal reception apparatus 120. First, the THz signal transmission apparatus 110 may include an arbitrary waveform generator 111 for generating a data signal to be transmitted. For example, the arbitrary waveform generator 111 may include an arrayed waveguide grating (AWG). However, the arbitrary waveform generator 111 is not limited to the above example, and may be configured in various forms.

The THz signal transmission apparatus 110 according to example embodiments may include a first light source 112 that outputs a data signal carrier, and may load a data signal on the data signal carrier through an optical modulator 113. In addition, the THz signal transmission apparatus 110 according to example embodiments may include a second light source 114 that outputs an optical carrier for generating a THz band signal, and a third light source 115 that outputs a reference carrier for generating a KK reception-based THz signal. In this case, the reference carrier outputted through the third light source 115, which is an essential element for implementing a KK reception-based KK receiver, may be outputted to have a size for satisfying a minimum phase condition for an operation of the KK receiver.

The THz signal transmission apparatus 110 according to example embodiments may generate the KK reception-based THz signal by photo-mixing, through a photo-mixer, the data signal carrier, the optical carrier, and the reference carrier respectively outputted through the first light source 112, the second light source 114, and the third light source 115. In this case, the photo-mixer 116 may be, for example, a unitraveling-carrier photodiode (UTC-PD), but is not limited to the above example, and various types of photo-mixers may be provided.

The THz signal transmission apparatus 110 may radiate the generated KK reception-based THz signal into air through an antenna 117, and the radiated KK reception-based THz signal may be collected through an antenna 121 of the THz signal reception apparatus 120.

The collected KK reception-based THz signal may be amplified through an optical amplifier 122, and then may be detected through an SBD 123, and digital signal processing (DSP) 125 may be performed on the KK reception-based THz signal through an oscilloscope 124.

In this case, when the first light source 112, the second light source 114, and the third light source 115 are not locked to one another, in the KK reception-based THz signal, a phase and frequency between a data signal career for a data signal to be transmitted, an optical carrier for generating a THz band signal, and a reference carrier for KK reception may not be locked, resulting in an issue related to the frequency offset, which may degrade a receiving end performance.

In response to the issue, the THz signal reception apparatus 120 according to example embodiments may provide a process for compensating for a frequency offset generated in a process of transmitting the THz signal, thereby resolving an issue related to degradation of a signal caused by the frequency offset.

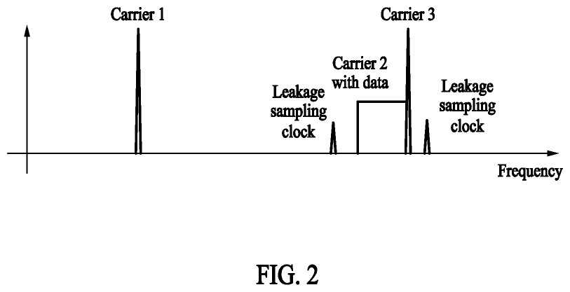

FIG. 2 is a diagram illustrating a frequency spectrum before photo-mixing of a KK reception-based THz signal according to an example embodiment.

Referring to FIG. 2, the KK reception-based THz signal may mainly include a data signal carrier Carrier 1 for a data signal to be transmitted, an optical carrier Carrier 2 for generating a THz band signal, and a reference carrier Carrier 3 for KK reception. In addition, the KK reception-based THz signal may include a sampling clock outputted from the arbitrary waveform generator 111 used to generate a data signal, and the like.

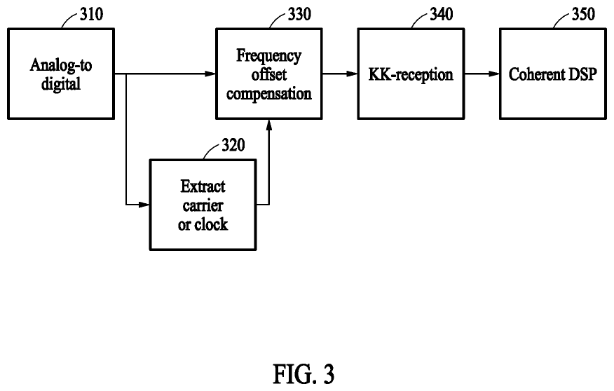

FIG. 3 is a diagram illustrating a method of compensating for a frequency offset according to an example embodiment.

Referring to FIG. 3, the method of compensating for a frequency offset for a KK reception-based THz signal may be applied to the DSP 125 stage of FIG. 1. First, the THz signal reception apparatus 120 may detect the collected KK reception-based THz signal with an ADC (operation 310).

Thereafter, the THz signal reception apparatus 120 may extract, on a specific frequency for the detected KK reception-based THz signal, a reference carrier for KK reception or a sampling clock outputted from the arbitrary waveform generator 111 and the like (operation 320), and may compensate for a frequency offset generated in a process of transmitting the THz signal by using the extracted reference carrier or sampling clock (operation 330).

More specifically, the reference carrier for KK reception may be inserted according to an intention of a designer when a transmitting end is designed, and initial frequency spectrum information on the reference carrier may be promised at a transmitting and receiving end. Accordingly, when the THZ signal reception apparatus 120 receives the reference carrier for KK reception, an initial position of the reference carrier may be verified based on the initial frequency spectrum information on the promised reference carrier.

In addition, in the case of the sampling clock, when a specification of the transmitting end is determined as a frequency used to generate a data signal, initial frequency spectrum information on the sampling clock may be verified therefrom by a receiving end, that is, the THz signal reception apparatus 120.

Accordingly, the THz signal reception apparatus 120 may identify, from the THz signal transmission apparatus 110, the initial frequency spectrum information on the reference carrier or sampling clock.

Thereafter, the THz signal reception apparatus 120 may extract current frequency spectrum information on the reference carrier or sampling clock of the received THz signal, and may compensate for a frequency offset of the THz signal by using the extracted current frequency spectrum information and the identified initial frequency spectrum information.

The THz signal reception apparatus 120 may perform KK reception-based DSP on the KK reception-based THz signal for which the frequency offset is compensated (operation 340), and may perform coherent-based DSP on the THz signal on which the KK reception-based DSP is performed (operation 350).

As described above, the THZ signal reception apparatus 120 according to example embodiments may compensate for the frequency offset generated in the process of transmitting the THZ signal by using the reference carrier for KK reception or the sampling clock generated in the process of generating the data signal, and thus a pilot signal and the like may not be required.

The method according to example embodiments may be written in a computer-executable program and may be implemented as various recording media such as magnetic storage media, optical reading media, or digital storage media.

Various techniques described herein may be implemented in digital electronic circuitry, computer hardware, firmware, software, or combinations thereof. The techniques may be implemented as a computer program product, i.e., a computer program tangibly embodied in an information carrier, e.g., in a machine-readable storage device (for example, a computer-readable medium) or in a propagated signal, for processing by, or to control an operation of, a data processing apparatus, e.g., a programmable processor, a computer, or multiple computers. A computer program, such as the computer program(s) described above, may be written in any form of a programming language, including compiled or interpreted languages, and may be deployed in any form, including as a stand-alone program or as a module, a component, a subroutine, or other units suitable for use in a computing environment. A computer program may be deployed to be processed on one computer or multiple computers at one site or distributed across multiple sites and interconnected by a communication network.

Processors suitable for processing of a computer program include, by way of example, both general and special purpose microprocessors, and any one or more processors of any kind of digital computer. Generally, a processor will receive instructions and data from a read-only memory or a random-access memory, or both. Elements of a computer may include at least one processor for executing instructions and one or more memory devices for storing instructions and data. Generally, a computer also may include, or be operatively coupled to receive data from or transfer data to, or both, one or more mass storage devices for storing data, e.g., magnetic, magneto-optical disks, or optical disks. Examples of information carriers suitable for embodying computer program instructions and data include semiconductor memory devices, e.g., magnetic media such as hard disks, floppy disks, and magnetic tape, optical media such as compact disk read only memory (CD-ROM) or digital video disks (DVDs), magneto-optical media such as floptical disks, read-only memory (ROM), random-access memory (RAM), flash memory, erasable programmable ROM (EPROM), or electrically erasable programmable ROM (EEPROM). The processor and the memory may be supplemented by, or incorporated in special purpose logic circuitry.

In addition, non-transitory computer-readable media may be any available media that may be accessed by a computer and may include both computer storage media and transmission media.

Although the present specification includes details of a plurality of specific example embodiments, the details should not be construed as limiting any invention or a scope that can be claimed, but rather should be construed as being descriptions of features that may be peculiar to specific example embodiments of specific inventions. Specific features described in the present specification in the context of individual example embodiments may be combined and implemented in a single example embodiment. On the contrary, various features described in the context of a single embodiment may be implemented in a plurality of example embodiments individually or in any appropriate sub-combination. Furthermore, although features may operate in a specific combination and may be initially depicted as being claimed, one or more features of a claimed combination may be excluded from the combination in some cases, and the claimed combination may be changed into a sub-combination or a modification of the sub-combination.

Likewise, although operations are depicted in a specific order in the drawings, it should not be understood that the operations must be performed in the depicted specific order or sequential order or all the shown operations must be performed in order to obtain a preferred result. In a specific case, multitasking and parallel processing may be advantageous. In addition, it should not be understood that the separation of various device components of the aforementioned example embodiments is required for all the example embodiments, and it should be understood that the aforementioned program components and apparatuses may be integrated into a single software product or packaged into multiple software products.

The example embodiments disclosed in the present specification and the drawings are intended merely to present specific examples in order to aid in understanding of the present disclosure, but are not intended to limit the scope of the present disclosure. It will be apparent to those skilled in the art that various modifications based on the technical spirit of the present disclosure, as well as the disclosed example embodiments, can be made.

The components described in the example embodiments may be implemented by hardware components including, for example, at least one digital signal processor (DSP), a processor, a controller, an application-specific integrated circuit (ASIC), a programmable logic element, such as a field programmable gate array (FPGA), other electronic devices, or combinations thereof. At least some of the functions or the processes described in the example embodiments may be implemented by software, and the software may be recorded on a recording medium. The components, the functions, and the processes described in the example embodiments may be implemented by a combination of hardware and software.

What is claimed is:

1. A method of compensating for a frequency offset performed by a terahertz (THz) signal reception apparatus, the method comprising:
receiving, from a THz signal transmission apparatus, a THz signal including carrier signals corresponding to three different frequency bands;
extracting, from the received THz signal, a reference carrier included in the THz signal or a sampling clock generated in a process of generating a data signal; and
compensating for a frequency offset generated in a process of transmitting the THz signal by using the extracted reference carrier or sampling clock.

2. The method of claim 1, wherein the THz signal is generated by photo-mixing the reference carrier, a data signal carrier for a data signal to be transmitted, and an optical carrier for generating a THz band signal.

3. The method of claim 1, wherein the compensating comprises:
identifying initial frequency spectrum information on the reference carrier or sampling clock of the THz signal received from the THz signal transmission apparatus;
extracting current frequency spectrum information on the reference carrier or sampling clock of the received THz signal; and
compensating for the frequency offset of the THz signal determined through the initial frequency spectrum information and the current frequency spectrum information on the reference carrier or sampling clock.

4. The method of claim 1, wherein the receiving comprises detecting the THz signal by using a Schottky-barrier-diode (SBD)-based detection method.

5. A terahertz (THz) signal reception apparatus comprising:
a receiver configured to receive, from a THz signal transmission apparatus, a THz signal including carrier signals corresponding to three different frequency bands; and
a processor configured to extract, from the THz signal received through the receiver, a reference carrier included in the THz signal or a sampling clock generated in a process of generating a data signal, and compensate for a frequency offset generated in a process of transmitting the THz signal by using the extracted reference carrier or sampling clock.

6. The THz signal reception apparatus of claim 5, wherein the THz signal is generated by photo-mixing the reference carrier, a data signal carrier for a data signal to be transmitted, and an optical carrier for generating a THz band signal.

7. The THz signal reception apparatus of claim 5, wherein the processor is configured to:
identify initial frequency spectrum information on the reference carrier or sampling clock of the THz signal received from the THz signal transmission apparatus;
extract current frequency spectrum information on the reference carrier or sampling clock of the received THz signal; and
compensate for the frequency offset of the THz signal determined through the initial frequency spectrum information and the current frequency spectrum information on the reference carrier or sampling clock.

8. The THz signal reception apparatus of claim 5, wherein a Schottky-barrier-diode (SBD)-based detection method is applied to the receiver.

9. A method of compensating for a frequency offset performed by a terahertz (THz) signal reception apparatus, the method comprising:
receiving, from a THz signal transmission apparatus, a THz signal including carrier signals corresponding to three different frequency bands, and converting the THz signal to a digital form;
extracting, from the THz signal converted to the digital form, a reference carrier included in the THz signal or a sampling clock generated in a process of generating a data signal;
compensating for a frequency offset generated in a process of transmitting the THz signal by using the extracted reference carrier or sampling clock;
performing Kramers-Kronig (KK) reception-based digital signal processing on the THz signal for which the frequency offset is compensated; and
performing coherent-based digital signal processing on the THz signal on which the KK reception-based digital signal processing is performed.

10. The method of claim 9, wherein the THz signal is generated by photo-mixing the reference carrier, a data signal carrier for a data signal to be transmitted, and an optical carrier for generating a THz band signal.

11. The method of claim 9, wherein the compensating comprises:
identifying initial frequency spectrum information on the reference carrier or sampling clock of the THz signal received from the THz signal transmission apparatus;
extracting current frequency spectrum information on the reference carrier or sampling clock of the received THz signal; and
compensating for the frequency offset of the THz signal determined through the initial frequency spectrum information and the current frequency spectrum information on the reference carrier or sampling clock.

12. The method of claim 9, wherein the THz signal is detected by using a Schottky-barrier-diode (SBD)-based detection method.
